(19) United States
(12) Patent Application Publication
(10) Pub. No.: US 2012/0141941 A1
(43) Pub. Date: Jun. 7, 2012

(54) DEVELOPING LITHOGRAPHIC PRINTING PLATE PRECURSORS IN SIMPLE MANNER

(76) Inventors: Mathias Jarek, Bad Gandersheim (DE); Domenico Balbinot, Osterode am Harz (DE); Harald Baumann, Osterode/Harz (DE)

(21) Appl. No.: 12/959,424

(22) Filed: Dec. 3, 2010

(51) Int. Cl. G03F 7/20; G03C 7/407

(52) U.S. Cl. 430/302; 430/434

(57) ABSTRACT

Imaged lithographic printing plates are processed using a developer that is replenished with only water, but replenishment is at a rate to allow developer volume to slowly decrease from a developer reservoir. This allows for a longer processing cycle especially when the developer is supplied from a container having a defined amount and applied using spray devices where water evaporation from the developer can be significant. Water lost by evaporation is replenished while water carried out by lithographic printing plates is not replenished.

### FIELD OF THE INVENTION

This invention relates to a method of processing (developing) imaged lithographic printing plate precursors with simple replenishment of the developer using water to compensate for evaporative loss of developer fluid. This method is particularly useful for processing imaged negative-working lithographic printing plate precursors.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink the ink receptive regions accept the ink and repel the water. The ink is then transferred to the surface of suitable materials upon which the image is to be reproduced. In some instances, the ink can be first transferred to an intermediate blanket that in turn is used to transfer the ink to the surface of the materials upon which the image is to be reproduced.

Lithographic printing plate precursors useful to prepare lithographic (or offset) printing plates typically comprise one or more imagable layers applied over a hydrophilic surface of a substrate (or intermediate layers). The imagable layer(s) can comprise one or more radiation-sensitive components dispersed within a suitable binder. Following imaging, either the exposed regions or the non-exposed regions of the imagable layer(s) are removed by a suitable developer, revealing the underlying hydrophilic surface of the substrate. If the exposed regions are removed, the element is considered as positive-working. Conversely, if the non-exposed regions are removed, the element is considered as negative-working. In each instance, the regions of the imagable layer(s) that remain are ink-receptive, and the regions of the hydrophilic surface revealed by the developing process accept water or aqueous solutions (typically a fountain solution), and repel ink.

“Laser direct imaging” methods (LDI) are used to directly form an offset printing plate or printing circuit board using digital data from a computer, and provide numerous advantages over the previous processes using masking photographic films. There has been considerable development in this field from more efficient lasers, improved imagable compositions and components thereof.

Various radiation-sensitive compositions are used in negative-working lithographic printing plate precursors as described for example in U.S. Pat. Nos. 6,309,792 (Hauck et al.), 6,893,797 (Munnelly et al.), 6,727,281 (Tao et al.), 6,899,994 (Huang et al.), and 7,429,445 (Munnelly et al.), U.S. Patent Application Publications 2002/0168494 (Nagata et al.), 2003/0118939 (West et al.), and EP Publications 1,079,276A2 (Lifka et al.) and 1,449,650A2 (Goto et al.).

After imaging, the negative-working lithographic printing plate precursors are developed (processed) to remove the non-imaged (non-exposed) regions of the imagable layer. Simplified processing solutions have been developed to be the only solution that is used to contact the precursor before printing. For example, U.S. Patent Application Publication 2009/0263746 (Ray et al.) describes the use of a single processing solution having a pH of 2 to 11 and containing an anionic surfactant to develop the imaged precursor as well as provide a protective coating over the printing surface. The processing solution can be applied in various ways including spraying, jetting, dipping, immersing, coating, and wiping techniques. Excess processing solution can be collected in a tank and used repeatedly, and replenished with “fresh” processing solution having the same or more concentrated form, which can be diluted with water.

EP Publication 1,091,253 (Yosida et al.) describes a method for processing by immersion in which the supply of developing is maintained at an optimum volume level by replenishing the developer with water (see FIGS. 2 and [0054]-[0056]).

EP Publication 2,045,662 (Oohashi) describes processing with a low pH developer that can be replenished in an automatic processor to maintain developer volume using fresh developer or water. Developer can be sprayed onto imaged precursors.

In addition, EP Publications 1,788,429 (Loccufier et al.), EP 1,788,430 (Loccufier et al.), 1,788,431 (Van Damme et al.), and 1,788,434 (Van Damme et al) describe the use of a gum as a developer, and it can be replenished using fresh gum, water, or a buffer based on the concentration of active products in the gum, gum viscosity, conductivity, or pH, or evaluation of solvent or water from the gum developer. There is no indication that the gum developer is replenished with water while its volume is decreased.

While some processing methods in the art require direct replenishment of the developer to maintain its volume and activity, other commercial processes simply use up developer from a container without any replenishment. This is the case for Agfa's commercial Azura processing technology (information available from Agfa's web site) that uses a 20-liter canister containing the developer that is used without any replenishment. The problem with this type of processing is that the cycle time is quite short. If the used developer is recycled to the canister, the developer solids content can increase (perhaps up to two times original concentration) because water has evaporated or been carried out by processed lithographic printing plates. As the solids content increases, apparatus rollers and processed lithographic printing plates are contaminated with dried residue, requiring additional cleaning or discarding ruined lithographic printing plates.

There is a need for a way to extend processing cycle time when containers are used to supply developers while lowering contamination of apparatus parts and processed lithographic printing plates.

### SUMMARY OF THE INVENTION

The present invention provides a method for preparing a plurality of lithographic printing plates using a processing solution for development, comprising:

processing a plurality of imaged lithographic printing plate precursors in a processing apparatus having a container containing a developer having a pH greater than 7 by applying the developer to the imaged lithographic printing plate precursors to provide lithographic printing plates,

wherein water is added to the container containing the developer while allowing the total volume of the developer in the container to decrease as processing of the imaged lithographic printing plate precursors proceeds.

The present invention provides a method for processing imaged lithographic printing plates to obtain longer cycle time so that more surface area can be processed with reduced contamination by residue on the processed printing plates and apparatus rollers. We found that these advantages could be achieved by replenishing the developer with only water but not replenishing to maintain the developer volume. Rather, the volume is allowed to steadily decrease but the rate of decrease is slowed from that which would occur if no replenishment occurred. In particular, this invention is useful to replenish developers supplied from enclosed canisters or other containers and from which the developer is delivered to the imaged lithographic printing plates by spraying devices. In effect, the replenishment using only water according to this invention essentially replaces water lost by evaporation from the developer but not the water carried out of the processing apparatus by the lithographic printing plates. The water lost from the developer by evaporation can be as much as six times the water carried out by processed lithographic printing plates.

Accordingly, since no additional surfactants, pH adjusting compounds, or organic solvents are used to extend the process cycle time of the single-bath developer, the present invention is more environmentally friendly, easier to handle, and less toxic for disposal.

### BRIEF DESCRIPTION OF THE DRAWINGS

FIG. 1 is a schematic illustration of a processing apparatus that can be used in the processing method of this invention.

FIG. 2 is a graphical representation of the change in % solids over a period of processing (loading of non-volatile components) as determined in Comparative Examples 1 and 2 and Invention Example 1 described below.

### DETAILED DESCRIPTION OF THE INVENTION

### Definitions

Unless the context indicates otherwise, when used herein, the terms “negative-working lithographic printing plate precursor”, “lithographic printing plate precursor”, “printing plate precursor”, and “precursor” are meant to be references to elements that can be processed using the present invention.

While the present invention is most advantageous for processing imaged negative-working lithographic printing plate precursors, it is not limited to those elements, but can also be used to process imaged positive-working lithographic printing plate precursors. However, the remaining disclosure will be focused on the negative-working elements only.

In addition, unless the context indicates otherwise, the various components described herein such as “infrared absorbing compound”, “infrared radiation absorbing compound”, “initiator”, “co-initiator”, “free radically polymerizable component”, “polymeric binder”, and various developer components described below, also refer to mixtures of such components. Thus, the use of the articles “a”, “an”, and “the” is not necessarily meant to refer to only a single component.

Moreover, unless otherwise indicated, percentages refer to percents by total dry weight, for example, weight % based on total solids of either an imagable layer or radiation-sensitive composition. Unless otherwise indicated, the percentages can be the same for either the dry imagable layer or the total solids of radiation-sensitive composition. When referring to developers as described below, weight % is generally based on the total developer weight including the water and any other solvents that are present.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imaging of Lithographic Printing Plate Precursors

During use, the lithographic printing plate precursor is exposed to a suitable source of exposing radiation depending upon the radiation absorbing compound present in the radiation-sensitive composition, at a wavelength of from about 250 to about 450 nm or from about 700 to about 1500 nm. For example, imaging can be carried out using imaging or exposing radiation, such as from an infrared laser (or an array of lasers) at a wavelength of at least 700 nm and up to and including about 1400 nm and typically at least 700 nm and up to and including 1200 nm. Imaging can be carried out using imaging radiation at multiple wavelengths at the same time if desired. Thus, this imaging provides both exposed (and hardened) regions and non-exposed (developer soluble or developer dispersible) regions in the imagable layer disposed on the hydrophilic substrate.

The laser used to expose the lithographic printing plate precursor is usually a diode laser (or array of diode lasers), because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imagable member mounted to the interior or exterior cylindrical surface of the drum. An example of an useful imaging apparatus is available as models of Kodak Trendsetter platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imagable layer.

Useful UV and “violet” imaging apparatus include Prosetter (from Heidelberger Druckmaschinen, Germany), Luxel V-8 (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), Laserjet (from Krause, Germany), and Andromeda® A750M (from Lithotech, Germany), imagesetters.

Imaging radiation in the UV to visible region of the spectrum, and particularly the UV region (for example at least 250 nm and up to and including 450 nm), can be carried out generally using energies of at least 0.01 mJ/cm² and up to and including 0.5 mJ/cm², and typically at least 0.02 and up to and including about 0.1 mJ/cm². It would be desirable, for example, to image the UV/visible radiation-sensitive lithographic printing plate precursors at a power density in the range of at least 0.5 and up to and including 50 kW/cm² and typically of at least 5 and up to and including 30 kW/cm², depending upon the source of energy (violet laser or excimer sources).

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

After imaging, a heating step (pre-heating) might be used to accelerate the formation of a latent image. This heating step can be realized in so called “preheat units” that can be a separate machine or integrated into the processor that develops the imaged precursor. There are different types of preheat units. The most common ones use infrared radiation or hot air circulation, or combination thereof, to heat the imaged precursor. The temperature used for the purpose is at least 70 and up to and including 200° C. However, it can be advantageous to omit the preheating step to simplify the process for making lithographic printing plates.

A pre-rinse step might be carried out in a stand-alone apparatus or by manually rinsing the imaged precursor with water or the pre-rinse step can be carried out in a washing unit that is integrated in a processor used for developing the imaged precursor.

### Development and Printing

After thermal imaging, the imaged precursors are processed (developed) “off-press” using a single aqueous processing solution that can be an aqueous alkaline processing solution having a pH of at least 7 and up to and including 12, or typically at least 8 and up to and including 11. Processing is carried out for a time sufficient to remove predominantly only the non-exposed regions of the imaged imagable layer of negative-working lithographic printing plate precursors to reveal the hydrophilic surface of the substrate, but not long enough to remove significant amounts of the exposed regions. The revealed hydrophilic surface repels inks while the exposed regions containing polymerized or crosslinked polymer accept ink. Thus, the non-exposed regions to be removed are “soluble” or “removable” in the aqueous alkaline solution because they are removed, dissolved, or dispersed within it more readily than the regions that are to remain. The term “soluble” also means “dispersible”.

Development can be accomplished using what is known as “manual” development, “dip” development, or processing with an automatic development apparatus (processor). In the case of “manual” development, development is conducted by rubbing the entire imaged precursor with a sponge or cotton pad sufficiently impregnated with a processing solution (described below), and optionally followed by rinsing with water. “Dip” development involves dipping the imaged precursor in a tank or tray containing the appropriate aqueous alkaline solution for at least 10 and up to and including 60 seconds under agitation, optionally followed by rinsing with water with or without rubbing with a sponge or cotton pad. The use of automatic development apparatus is well known and generally includes pumping an aqueous alkaline solution into a developing tank or ejecting it from spray nozzles. The apparatus can also include a suitable rubbing mechanism (for example a brush or roller) and a suitable number of conveyance rollers. Some developing apparatus include laser exposure means and the apparatus is divided into an imaging section and a developing section.

For example, the method of this invention can be carried out by processing the image lithographic printing plate precursors using developer as described herein by applying the developer from a container (such as a developer canister) containing the developer while adding water to the developer but allowing the total volume of developer in the container to decrease as processing proceeds. The amount or rate of water addition is designed to extend the processing cycle without measurably causing the deposition of residue on the lithographic printing plates or processing apparatus parts (such as rollers). The ways the water rate is determined can vary and is readily determined by routine experimentation.

For example, in some embodiments, the water can be added to the container containing the developer at a constant rate per unit area of imaged lithographic printing plate precursors being processed. The particular unit area of imaged precursor can be routinely determined for a given lithographic printing plate precursor and its imaging chemistry and the particular developer being used, by routine testing to see how much water should be added over time to extend the processing cycle without residue deposition as described above. For example, such routine testing can include developing an imaged lithographic printing plate precursor and determining the amount of developer that is carried out of the processing chamber by the developed lithographic printing plates.

In other embodiments, the water is added to the container containing the developer at a constant rate per unit time that the developer is applied to the imaged lithographic printing plate precursors being processed. This rate per unit time can also be determined by routine experimentation, for example by weighing the container containing the developer both before and after a specific processing time period. For example, the developer can be applied by a spray device (comprising one or more spray nozzles) and the water is added to the container containing the developer at a constant rate per unit time the spray device is activated to apply the developer to the imaged lithographic printing plate precursors. Sprayed developer can be directed onto the imaged surface of the lithographic printing plate precursor at a distance of at least 1 cm from the precursor surface.

In other embodiments, water is added to the developer container at a constant rate per unit area of imaged lithographic printing plate precursors being processed, and at a constant rate per unit time when no precursors are being processed and the processor is in idle mode.

In the practice of this invention, the non-volatile components (for example, polymeric binders and surfactants) in the developer can be maintained in the container containing the developer within ±5% (or typically ±2%) of the original non-volatile component concentration in fresh developer. Within these ranges, it is less likely that non-volatile components are deposited on the processed precursors or apparatus rollers.

Alternatively or in addition, the density of the developer can be maintained in the container containing the developer within ±1% (or typically ±0.5%) of the original density of fresh developer. Density of the developer can be tested at various times during a processing cycle by using a densitometer.

The processing apparatus used in the practice of this invention can further comprise:

at least one spray device for applying the developer to the plurality of imaged lithographic printing plate precursors,

at least one pair of rollers (for example squeegee rollers) for removing developer from the imaged lithographic printing plate precursors after the developer is sprayed thereon, and

a collection device for collecting developer that is not carried away by the plurality of lithographic printing plates.

The processing apparatus can also include a container from which water is supplied to the container containing the developer.

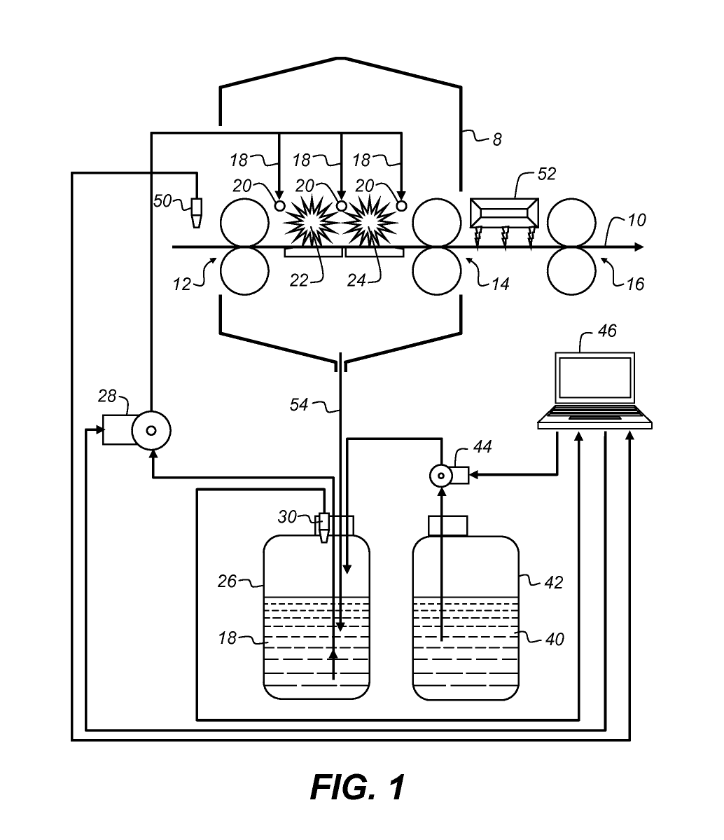

A particularly useful processing apparatus is described in FIG. 1 in which imaged lithographic printing plate precursors are processed in processing chamber 8 while being conveyed in the direction of arrow 10 using conveyance rollers pairs 12, 14, and 16. Between conveyance roller pairs 12 and 14, the conveyed precursors are contacted with developer 18 from spray devices 20 while rotating brushes 22 and 24 are used to facilitate removal of non-exposed regions of the imaged surface of the lithographic printing plate precursors. Developer 18 is supplied to spray devices 20 from developer canister 26 using the force from developer pump 28. The level of developer 18 in developer canister 26 can be monitored using developer level sensor 30.

Water 40 is supplied to the developer canister 26 from water canister 42 using the force from water pump 44. The amount of water 40 supplied to developer canister 26 can be determined and controlled using data gathered and manipulated using computer 46 that gathers data, for example, from developer level sensor 30, conveyed precursor sensor 50, and other necessary sources within and outside the processing apparatus and sends instructions to developer pump 28 and water pump 44. The addition of water 40 to developer canister 26 is thus designed to replace most or all of the water that is evaporated during processing of the imaged precursors, but is not designed to replace water that is carried out of processing chamber 8 into drying chamber 52. It is also possible to collect used developer from processing chamber 8 and return it to developer canister 26 as shown by arrow 54.

Useful developers or processing solutions for this invention commonly include surfactants, chelating agents (such as salts of ethylenediaminetetraacetic acid), organic solvents (such as benzyl alcohol), and alkaline components (such as inorganic metasilicates, organic metasilicates, hydroxides, and bicarbonates). Both aqueous alkaline developers and organic solvent-containing developers can be used.

Useful alkaline aqueous developers include but are not limited to, 3000 Developer, 9000 Developer, GOLDSTAR Developer, GREENSTAR Developer, ThermalPro Developer, PROTHERM Developer, MX1813 Developer, and MX1710 Developer (all available from Eastman Kodak Company).

Organic solvent-containing developers are generally single-phase processing solutions of one or more organic solvents that are miscible with water. Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. The organic solvent(s) is generally present in an amount of from about 0.5 and up to 15% based on total developer weight. The organic solvent-containing developers can be neutral, alkaline, or slightly acidic in pH, and preferably, they are alkaline in pH.

Representative solvent-containing developers include but are not limited to, ND-1 Developer, Developer 980, Developer 1080, 2 in 1 Developer, 955 Developer, D29 Developer (described below), and 956 Developer (all available from Eastman Kodak Company). These developers can be diluted with water if desired.

Other useful solvent-containing developers are described in copending and commonly assigned U.S. Serial No. 1______/______ (filed on even date herewith by Balbinot, Jarek, Huang, Tao, and Simpson and entitled METHOD OF PREPARING LITHOGRAPHIC PRINTING PLATES, Attorney Docket 96526/JLT). These developers contain anionic surfactants and organic solvents (such as benzyl alcohol) in an amount of at least 7 weight %. Another useful developer is described in copending and commonly assigned U.S. Serial No. 1______/______ (filed on even date herewith by Strehmel, Piestert, and Baumann and entitled DEVELOPER AND ITS USE TO PREPARE LITHOGRAPHIC PRINTING PLATES, Attorney Docket 96527/JLT).

In some instances, an aqueous processing solution can be used to both develop the imaged precursor by removing predominantly the non-exposed regions and also to provide a protective layer or coating over the entire imaged and developed surface. In this aspect, the aqueous alkaline solution behaves somewhat like a gum that is capable of protecting (or “gumming”) the lithographic image on the printing plate against contamination or damage (for example, from oxidation, fingerprints, dust, or scratches). The aqueous alkaline solution generally includes an organic amine having a boiling point of less than 300° C. (and typically of at least 50°), a film-forming hydrophilic polymer, and optionally an anionic or nonionic surfactant. The pH of the aqueous alkaline solution can be adjusted by adding a suitable amount of a alkaline component such as alkali silicates (including metasilicates), alkali metal hydroxides (such as sodium hydroxide and potassium hydroxide), and quaternary ammonium hydroxides. Tap water can be used to make up the solution and generally provides at least 45 and up to and including 98 weight % of the solution.

Useful organic amines are relatively volatile organic primary, secondary, and tertiary amines that include but are not limited to, alkanolamines (including cycloalkyl amines), carbocyclic aromatic amines, and heterocyclic amines, that are present in a total amount of at least 0.1 weight % and generally up to and including 50 weight %. Useful amines are mono-, di- and trialkanol amines such as monoethanolamine, diethanolamine, triethanolamine, and mono-n-propanolamine, or combinations of these compounds.

One or more film-forming water-soluble or hydrophilic polymers are present in the aqueous alkaline solution in an amount of at least 0.25 weight % and up to 30 weight % and typically at least 1 and up to and including 15 weight %. Examples of useful polymers of this type include but are not limited to, gum arabic, pullulan, cellulose derivatives (such as hydroxymethyl celluloses, carboxymethylcelluloses, carboxyethylcelluloses, and methyl celluloses), starch derivatives [such as (cyclo)dextrins, starch esters, dextrins, carboxymethyl starch, and acetylated starch] poly(vinyl alcohol), poly(vinyl pyrrolidone), polyhydroxy compounds [such as polysaccharides, sugar alcohols such as sorbitol, miso-inosit, homo- and copolymers of (meth)acrylic acid or (meth)acrylamide], copolymers of vinyl methyl ether and maleic anhydride, copolymers of vinyl acetate and maleic anhydride, copolymers of styrene and maleic anhydride, and copolymers having recurring units with carboxy, sulfo, or phospho groups, or salts thereof. Useful hydrophilic polymers include gum arabic, (cyclo)dextrin, a polysaccharide, a sugar alcohol, or a homo- or copolymer having recurring units derived from (meth)acrylic acid.

The aqueous alkaline solution optionally includes one or more anionic, amphoteric, or nonionic surfactants (or both) in an amount of at least 0.25 and up to and including 50 weight %, and typically at least 0.25 and up to and including 30 weight %.

Additional optional components of the aqueous alkaline solutions used in this invention include antifoaming agents, buffers, biocides, complexing agents, and small amounts of water-miscible organic solvents such as reaction products of phenol with ethylene oxide and propylene oxide, benzyl alcohol, esters of ethylene glycol and propylene glycol with acids having 6 or less carbon atoms, sludge inhibitors (such as filter dyes and free-radical inhibitors), odorants, anti-corrosion agents, and dyes.

Following processing, the resulting lithographic printing plate can be used for printing with or without a separate rinsing step using water. In most instances, the lithographic printing plates are used for printing after development without further contact with any additional solutions such as rinsing or gumming solutions.

The resulting lithographic printing plate can also be baked in a postbake operation can be carried out, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and developed precursor. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material.

### Substrates

The substrate used to prepare the lithographic printing plate precursors comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful substrate is an aluminum-containing support that can be treated using techniques known in the art, including roughening of some type by physical (mechanical) graining, electrochemical graining, or chemical graining, usually followed by acid anodizing. The aluminum-containing support can be roughened by physical or electrochemical graining and then anodized using phosphoric or sulfuric acid (or a mixture of both phosphoric and sulfuric acids) and conventional procedures. A useful hydrophilic lithographic substrate is an electrochemically grained and sulfuric acid-anodized aluminum-containing substrate that provides a hydrophilic surface for lithographic printing.

Sulfuric acid anodization of the aluminum support generally provides an oxide weight (coverage) on the surface of at least 1.5 and up to and including 5 g/m², and can provide longer press life. Phosphoric acid anodization generally provides an oxide weight on the surface of at least 1 and up to and including 5 g/m².

The aluminum-containing substrate can also be post-treated with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or an acrylic acid copolymer to increase hydrophilicity. Still further, the aluminum-containing substrate can be treated with a phosphate solution that can further contain an inorganic fluoride (PF). It is particularly useful to post-treat the sulfuric acid-anodized aluminum-containing substrate with either poly(acrylic acid) or poly(vinyl phosphonic acid).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Negative-working Lithographic Printing Plate Precursors

The precursors can be formed by suitable application of a radiation-sensitive composition as described below to a suitable substrate (described above) to form an imagable layer. There is generally only a single imagable layer comprising the radiation-sensitive composition and can be the outermost layer in the element. However, such a topcoat can be present over the imagable layers designed for off-press development.

Negative-working lithographic printing plate precursors are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. Nos. 4,511,645 (Koike et al.), 6,027,857 (Teng), 6,309,792 (Hauck et al.), 6,569,603 (Furukawa et al.), 6,899,994 (Huang et al.), 7,045,271 (Tao et al.), 7,049,046 (Tao et al.), 7,261,998 (Hayashi et al.), 7,279,255 (Tao et al.), 7,285,372 (Baumann et al.), 7,291,438 (Sakurai et al.), 7,326,521 (Tao et al.), 7,332,253 (Tao et al.), 7,442,486 (Baumann et al.), 7,452,638 (Yu et al.), 7,524,614 (Tao et al.), 7,560,221 (Timpe et al.), 7,574,959 (Baumann et al.), 7,615,323 (Shrehmel et al.), and 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.), all of which are incorporated herein by reference. Other negative-working compositions and elements are described for example in U.S. Pat. Nos. 6,232,038 (Takasaki), 6,627,380 (Saito et al.), 6,514,657 (Sakurai et al.), 6,808,857 (Miyamoto et al.), and U.S. Patent Publication 2009/0092923 (Hayashi), all of which are incorporated herein by reference.

The radiation-sensitive compositions and imagable layers used in such precursors can generally include one or more polymeric binders that facilitate the developability of the imaged precursors. Such polymeric binders include but are not limited to, those that are not generally crosslinkable and are usually present at least partially as discrete particles (not-agglomerated). Such polymers can be present as discrete particles having an average particle size of at least 10 and up to and including 500 nm, and typically at least 100 and up to and including 450 nm, and that are generally distributed uniformly within that layer. The particulate polymeric binders exist at room temperature as discrete particles, for example in an aqueous dispersion. Such polymeric binders generally have a molecular weight (Mₙ) of at least 5,000 and typically at least 20,000 and up to and including 100,000, or at least 30,000 and up to and including 80,000, as determined by Gel Permeation Chromatography. Useful particulate polymeric binders generally include polymeric emulsions or dispersions of polymers having hydrophobic backbones to which are directly or indirectly linked pendant poly(alkylene oxide) side chains (for example at least 10 alkylene glycol units), cyano side chains, or both types of side chains, that are described for example in U.S. Pat. Nos. 6,582,882 (Pappas et al.), 6,899,994 (Huang et al.), 7,005,234 (Hoshi et al.), and 7,368,215 (Munnelly et al.) and US Patent Application Publication 2005/0003285 (Hayashi et al.), all of which are incorporated herein by reference. More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, in recurring units arranged in random fashion to form the polymer backbone, and various hydrophilic polymeric binders that can have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the particulate polymeric binders can also have a backbone comprising multiple (at least two) urethane moieties. Such polymeric binders generally have a molecular weight (Mₙ) of at least 2,000 and typically at least 100,000 and up to and including 500,000, or at least 100,000 and up to and including 300,000, as determined by dynamic light scattering.

Additional useful polymeric binders are particulate poly(urethane-acrylic) hybrids that are distributed (usually uniformly) throughout the imagable layer. Each of these hybrids has a molecular weight of at least 50,000 and up to and including 500,000 and the particles have an average particle size of at least 10 and up to and including 10,000 nm (typically at least 30 and up to and including 500 nm or at least 30 and up to and including 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that can also include commercial surfactants, anti-foaming agents, dispersing agents, anti-corrosive agents, and optionally pigments and water-miscible organic solvents.

These polymeric binders are generally present in an amount of at least 5 and up to and including 70 weight % of the radiation-sensitive composition.

Other useful polymeric binders can be homogenous, that is, non-particulate or dissolved in the coating solvent, or they can exist as discrete particles. Such polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. Nos. 6,309,792 (Hauck et al.), 6,352,812 (Shimazu et al.), 6,569,603 (Furukawa et al.), and 6,893,797 (Munnelly et al.), all of which are incorporated herein by reference. Also useful are the vinyl carbazole polymers described in U.S. Pat. No. 7,175,949 (Tao et al.), and the polymers having pendant vinyl groups as described in U.S. Pat. No. 7,279,255 (Tao et al.), both patents being incorporated herein by reference. Useful are random copolymers derived from polyethylene glycol methacrylate/acrylonitrile/styrene monomers in random fashion and in particulate form, dissolved random copolymers derived from carboxyphenyl methacrylamide/acrylonitrile/-methacrylamide/N-phenyl maleimide, random copolymers derived from polyethylene glycol methacrylate/acrylonitrile/vinyl carbazole/styrene/-methacrylic acid, random copolymers derived from N-phenyl maleimide/methacrylamide/methacrylic acid, random copolymers derived from urethane-acrylic intermediate A (the reaction product of p-toluene sulfonyl isocyanate and hydroxylethyl methacrylate)/acrylonitrile/N-phenyl maleimide, and random copolymers derived from N-methoxymethyl methacrylamide/methacrylic acid/acrylonitrile/n-phenylmaleimide. By “random” copolymers, we mean the conventional use of the term, that is, the structural units in the polymer backbone that are derived from the monomers are arranged in random order as opposed to being block copolymers, although two or more of the same structural units can be in a chain incidentally.

Thus, the polymeric binders can be selected from any alkaline solution soluble (or dispersible) polymer having an acid value of at least 20 and up to and including 400 (typically at least 30 and up to and including 200). The following described polymeric binders are particularly useful in the manner but this is not an exhaustive list:

I. Polymers formed by polymerization of a combination or mixture of (a) (meth)acrylonitrile, (b) poly(alkylene oxide) esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference. Some particularly useful polymeric binders in this class are derived from one or more (meth)acrylic acids, (meth)acrylate esters, styrene and its derivatives, vinyl carbazoles, and poly(alkylene oxide) (meth)acrylates.

II. Polymers having pendant allyl ester groups as described in U.S. Pat. No. 7,332,253 (Tao et al.) that is incorporated herein by reference. Such polymers can also include pendant cyano groups or have recurring units derived from a variety of other monomers as described in Col. 8, line 31 to Col. 10, line 3 of the noted patent.

III. Polymers having all carbon backbones wherein at least 40 and up to and including 100 mol % (and typically at least 40 and up to and including 50 mol %) of the carbon atoms forming the all carbon backbones are tertiary carbon atoms, and the remaining carbon atoms in the all carbon backbone being non-tertiary carbon atoms. By “tertiary carbon”, we refer to a carbon atom in the all carbon backbone that has three valences filled with radicals or atoms other than a hydrogen atom (which fills the fourth valence). By “non-tertiary carbon”, we mean a carbon atom in the all carbon backbone that is a secondary carbon (having two valences filled with hydrogen atoms) or a quaternary carbon (having no hydrogen atoms attached). Typically, most of the non-tertiary carbon atoms are secondary carbon atoms. One way to represent a tertiary carbon atom in the all carbon backbone is with the following Structure (T-CARBON):

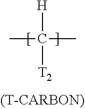

wherein T₂ is a group other than hydrogen provided that T₂ does not include an ethylenically unsaturated free radically reactive group (such as a —C═C— group). In many embodiments, T₂ is a pendant group selected from N-carbazole, aryl (defined similarly as for Ar below), halo, cyano, —C(═O)R, —C(═O)Ar, —C(═O)OR, —C(═O)OAr, —C(═O)NHR, and —C(═O)NHAr pendant groups, wherein R is hydrogen or an alkyl, cycloalkyl, halo, alkoxy, acyl, or acyloxy group, and Ar is an aryl group other than a styryl group. The quaternary carbon atoms present in the all carbon backbone of the polymeric binder can also have the same or different pendant groups filling two of the valences. For example, one or both valences can be filled with the same or different alkyl groups as defined above for R, or one valence can be filled with an alkyl group and another valence can be filled with a N-carbazole, aryl other than a styryl group, halo, cyano, —C(═O)R, —C(═O)Ar, —C(═O)OR, —C(═O)OAr, —C(═O)NHR, or —C(═O)NHAr pendant group, wherein R and Ar are as defined above. The pendant groups attached to the tertiary and quaternary carbons in the all carbon backbone can be the same or different and typically, they are different. It should also be understood that the pendant groups attached to the various tertiary carbon atoms can be the same throughout the polymeric molecule, or they can be different. For example, the tertiary carbon atoms can be derived from the same or different ethylenically unsaturated polymerizable monomers. Moreover, the quaternary carbon atoms throughout the polymeric molecule can have the same or different pendant groups.

In some embodiments, the polymeric binder can be represented by the following Structure:

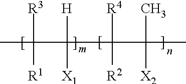

that is defined in more details in U.S. Patent Application Publication 2008-0280229 (Tao et al.) that is incorporated herein by reference.

Representative recurring units comprising tertiary carbon atoms can be derived from one or more ethylenically unsaturated polymerizable monomers selected from vinyl carbazole, styrene and derivatives thereof (other than divinylbenzene and similar monomers that provide pendant carbon-carbon polymerizable groups), acrylic acid, acrylonitrile, acrylamides, acrylates, and methyl vinyl ketone. As noted above, two or more different recurring units can be used. Similarly, representative recurring units with secondary or quaternary carbon atoms can be derived from one or more ethylenically unsaturated polymerizable monomers selected from methacrylic acid, methacrylates, methacrylamides, and a-methylstyrene.

IV. Polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups can be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. Nos. 4,874,686 (Urabe et al.), 7,729,255 (Tao et al.), 6,916,595 (Fujimaki et al.), and 7,041,416 (Wakata et al.) that are incorporated by reference, especially with respect to the general formulae (1) through (3) noted in EP 1,182,033A1.

V. Polymeric binders can have pendant 1H-tetrazole groups as described in U.S. Patent Application Publication 2009-0142695 (Baumann et al.) that is incorporated herein by reference.

VI. Still other useful polymeric binders can be homogenous, that is, dissolved in the coating solvent, or can exist as discrete particles and include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (noted above) and U.S. Pat. Nos. 6,309,792 (Hauck et al.), 6,352,812 (Shimazu et al.), 6,569,603 (noted above), and 6,893,797 (Munnelly et al.). Also useful are the vinyl carbazole polymers described in U.S. Pat. No. 7,175,949 (Tao et al.). Other useful polymeric binders are particulate poly(urethane-acrylic) hybrids that are distributed (usually uniformly) throughout the imagable layer. Each of these hybrids has a molecular weight of at least 50,000 and up to and including 500,000 and the particles have an average particle size of at least 10 and up to and including 10,000 nm (typically at least 30 and up to and including 500 nm).

The radiation-sensitive composition (and imagable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. Nos. 6,309,792 (Hauck et al.), 6,569,603 (Furukawa), and 6,893,797 (Munnelly et al.). Other useful free radically polymerizable components include those described in U.S. Patent Application Publication 2009/0142695 (Baumann et al.), which radically polymerizable components include 1H-tetrazole groups.

In addition to, or in place of the free radically polymerizable components described above, the radiation-sensitive composition can include polymeric materials that include side chains attached to the backbone, which side chains include one or more free radically polymerizable groups (such as ethylenically unsaturated groups) that can be polymerized (crosslinked) in response to free radicals produced by the initiator composition (described below). There can be at least two of these side chains per molecule. The free radically polymerizable groups (or ethylenically unsaturated groups) can be part of aliphatic or aromatic acrylate side chains attached to the polymeric backbone. Generally, there are at least 2 and up to and including 20 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

This radiation-sensitive composition also includes an initiator composition that includes one or more initiators that are capable of generating free radicals sufficient to initiate polymerization of all the various free radically polymerizable components upon exposure of the composition to imaging infrared radiation. The initiator composition is generally responsive, for example, to electromagnetic radiation in the infrared spectral regions, corresponding to the broad spectral range of at least 700 nm and up to and including 1400 nm, and typically radiation of at least 700 nm and up to and including 1250 nm. Alternatively, the initiator composition may be responsive to exposing radiation in the violet region of at least 250 and up to and including 450 nm and typically at least 300 and up to and including 450 nm.

More typically, the initiator composition includes one or more an electron acceptors and one or more co-initiators that are capable of donating electrons, hydrogen atoms, or a hydrocarbon radical.

In general, suitable initiator compositions for radiation-sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators”described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts).

Hexaarylbiimidazoles, onium compounds, and thiol compounds as well as mixtures of two or more thereof are desired coinitiators or free radical generators, and especially hexaarylbiimidazoles and mixtures thereof with thiol compounds are useful. Suitable hexaarylbiimidazoles are also described in U.S. Pat. Nos. 4,565,769 (Dueber et al.) and 3,445,232 (Shirey) and can be prepared according to known methods, such as the oxidative dimerization of triarylimidazoles.

Useful initiator compositions for IR radiation-sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions can be supplied as part of substituted or unsubstituted diaryliodonium salts that are combinations of Structures (I) and (II) described in Cols. 6-8 of U.S. Pat. No. 7,524,614 (Tao et al.) that is incorporated herein by reference.

Useful IR radiation-sensitive initiator compositions can comprise one or more diaryliodonium borate compounds. Representative iodonium borate compounds useful in this invention include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexyl-phenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexyl-phenyliodonium tetrakis(penta-fluorophenyl)borate, 4-methylphenyl-4′-dodecylphenyliodonium tetrakis(4-fluorophenyl)borate, bis(dodecylphenyl)-iodonium tetrakis(pentafluorophenyl)-borate, and bis(4-t-butylphenyl)iodonium tetrakis(1-imidazolyl)borate. Useful compounds include bis(4-t-butylphenyl)-iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

The imagable layers comprise a radiation-sensitive imaging composition that includes one or more infrared radiation absorbing compounds or one or more UV sensitizers. The total amount of one or more infrared radiation absorbing compounds or sensitizers is at least 1 and up to and including 30 weight %, or typically at least 5 and up to and including 20 weight %, based on the imagable layer total solids.

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 375 nm and up to and including 475 nm. Useful sensitizers for such compositions include certain pyrilium and thiopyrilium dyes and 3-ketocoumarins. Some other useful sensitizers for such spectral sensitivity are described for example, in 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated 7E-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Other useful sensitizers for the violet region of sensitization are the 2,4,5-triaryloxazole derivatives as described in WO 2004/074930 (Baumann et al.). These compounds can be used alone or with a co-initiator as described above. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan or oxazole ring, or the Structure G-(Ar₁)₂ wherein G is an oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Thus, the aryl groups can be substituted with one or more R′₁, through R′₃ groups, respectively, that are independently hydrogen or a substituted or unsubstituted alkyl group having from 1 to 20 carbon atoms (such as methyl, ethyl, iso-propyl, n-hexyl, benzyl, and methoxymethyl groups) substituted or unsubstituted carbocyclic aryl group having 6 to 10 carbon atoms in the ring (such as phenyl, naphthyl, 4-methoxyphenyl, and 3-methylphenyl groups), substituted or unsubstituted cycloalkyl group having 5 to 10 carbon atoms in the ring, a —N(R′₄)(R′₅) group, or a —OR′₆ group wherein R′₄ through R′₆ independently represent substituted or unsubstituted alkyl or aryl groups as defined above. At least one of R′₁, through R′₃ is an —N(R′₄)(R′₅) group wherein R′₄ and R′₅ are the same or different alkyl groups. Useful substituents for each Ar₁ group include the same or different primary, secondary, and tertiary amines.

Still another class of useful violet radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, oxazole, or oxadiazole ring. Ar₁ is the same as defined above, and Ar₂ can be the same or different aryl group as Ar₁. “Arylene” can be any of the aryl groups defined for Ar₁ but with a hydrogen atom removed to render them divalent in nature.

Some useful infrared radiation absorbing compounds are sensitive to both infrared radiation (typically of at least 700 and up to and including 1400 nm) and visible radiation (typically of at least 450 and up to and including 700 nm). These compounds also have a tetraaryl pentadiene chromophore. Such chromophore generally includes a pentadiene linking group having 5 carbon atoms in the chain, to which are attached two substituted or unsubstituted aryl groups at each end of the linking group. These aryl groups can be substituted with the same or different tertiary amine groups. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain. Other details of such compounds are provided in U.S. Pat. No. 7,429,445 (Munnelly et al.)

Other useful include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. Nos. 5,208,135 (Patel et al.), 6,153,356 (Urano et al.), 6,264,920 (Achilefu et al.), 6,309,792 (Hauck et al.), 6,569,603 (noted above), 6,787,281 (Tao et al.), 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (noted above), 6,264,920

(Achilefu et al.), 6,153,356 (noted above), and 5,496,903 (Watanabe et al.). Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described in U.S. Pat. No. 4,973,572 (DeBoer).

Useful IR-radiation sensitive compositions are described, for example, in U.S. Pat. No. 7,452,638 (Yu et al.), and U.S. Patent Application Publications 2008/0254387 (Yu et al.), 2008/0311520 (Yu et al.), 2009/0263746 (Ray et al.), and 2010/0021844 (Yu et al.).

The imagable layer can also include a poly(alkylene glycol) or an ether or ester thereof that has a molecular weight of at least 200 and up to and including 4000. The imagable layer can further include a poly(vinyl alcohol), a poly(vinyl pyrrolidone), poly(vinyl imidazole), or polyester in an amount of up to and including 20 weight % based on the total dry weight of the imagable layer.

Additional additives to the imagable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.). The imagable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. The imagable layer also optionally includes a phosphate (meth)acrylate having a molecular weight generally greater than 250 as described in U.S. Pat. No. 7,429,445 (Munnelly et al.) that is incorporated herein by reference.

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imagable layer.

The outermost layer can be a water-soluble or water-dispersible overcoat (also sometimes known as an “oxygen impermeable topcoat” or “oxygen barrier layer”) disposed over the imagable layer. Such overcoat layers can comprise one or more water-soluble poly(vinyl alcohol)s having a saponification degree of at least 90% and generally have a dry coating weight of at least 0.1 and up to and including 2 g/m² in which the water-soluble poly(vinyl alcohol)s comprise at least 60% and up to and including 99% of the dry overcoat layer weight.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a random copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), and random copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.) that is incorporated by reference.

Illustrative of such manufacturing methods is mixing the various components needed for a specific imaging chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imagable layer formulations are described in the Invention Examples below. After proper drying, the coating weight of the imagable layer is generally at least 0.1 and up to and including 5 g/m² or at least 0.5 and up to and including 3.5 g/m².

Layers can also be present under the imagable layer to enhance developability or to act as a thermal insulating layer.

Once the various layers have been applied and dried on the substrate, the negative-working imagable elements can be enclosed in water-impermeable material that substantially inhibits the transfer of moisture to and from the element and “heat conditioned” as described in U.S. Pat. No. 7,175,969 (noted above) that is incorporated herein by reference.

The lithographic printing plate precursors can be stored and transported as stacks of precursors within suitable packaging and containers known in the art.

The present invention provides at least the following embodiments and combinations thereof, but other combinations of features are considered to be within the present invention as a skilled artisan would appreciate from the teaching of this disclosure:

1. A method for preparing a plurality of lithographic printing plates using a processing solution for development, comprising:

processing a plurality of imaged lithographic printing plate precursors in a processing apparatus having a container containing a developer having a pH greater than 7 by applying the developer to the imaged lithographic printing plate precursors to provide lithographic printing plates,

wherein water is added to the container containing the developer while allowing the total volume of the developer in the container to decrease as processing of the imaged lithographic printing plate precursors proceeds.

2. The method of embodiment 1 wherein the processing apparatus further comprises:

at least one spray device for applying the developer to the plurality of imaged lithographic printing plate precursors,

at least one pair of rollers for removing developer from the imaged lithographic printing plate precursors after the developer is sprayed thereon, and

a collection device for collecting developer that is not carried away by the plurality of lithographic printing plates.

3. The method of embodiment 1 or 2 wherein the processing apparatus further includes a container containing water that can be supplied to the container containing the developer.

4. The method of any of embodiments 1 to 3 wherein the water is added to the container containing the developer at a constant rate per unit area of imaged lithographic printing plate precursors being processed.

5. The method of any of embodiments 1 to 4 wherein the water is added to the container containing the developer at a constant rate per unit time that the developer is applied to the imaged lithographic printing plate precursors being processed.

6. The method of any of embodiments 1 to 5 wherein the developer is applied by a spray device and the water is added to a container containing the developer at a constant rate per unit time the spray device is activated to apply the developer to the imaged lithographic printing plate precursors.

7. The method of any of embodiments 1 to 6 wherein the non-volatile components in the developer is maintained in the container containing the developer within ±5% of the original non-volatile component concentration in fresh developer.

8. The method of any of embodiments 1 to 6 wherein the density of the developer is maintained in the container containing the developer within ±1% of the original density of fresh developer.

9. The method of any of embodiments 1 to 8 wherein the developer is designed to both develop the imaged lithographic printing plate precursor as well as provide a protective coating over the printing surface of the resulting lithographic printing plate.

10. The method of any of embodiments 1 to 9 wherein the developer has a pH of at least 8 and up to and including 11.

11. The method of any of embodiments 1 to 10 further comprising imaging the lithographic printing plate precursor to provide exposed and non-exposed regions prior to processing with the developer.

12. The method of any of embodiments 1 to 11 wherein the imaged lithographic printing plate precursor is processed by spraying the developer onto its imaged surface at a distance of at least 1 cm from the precursor surface.

13. The method of any of embodiments 1 to 12 for processing an imaged negative-working lithographic printing plate precursor comprising an imaged negative-working imagable layer to remove non-exposed regions in the imagable layer.

The following Examples are provided to illustrate the practice of this invention and are not meant to be limiting in any manner.

To illustrate the present invention, samples of negative-working Trilliam SP lithographic printing plate precursors (available from Eastman Kodak Company) were imaged using a Kodak® Trendsetter 800 II Quantum platesetter (830 nm) at 80 mJ/cm² exposure energy, and then processed using a processing apparatus like that shown in FIG. 1. In preliminary processing tests, we determined that the water lost by being carried out by each processed lithographic printing plate was 3 g/m². However, the water loss from evaporation loss after 250 m² surface area had been processed was 20 g/m².

### Comparative Example 1

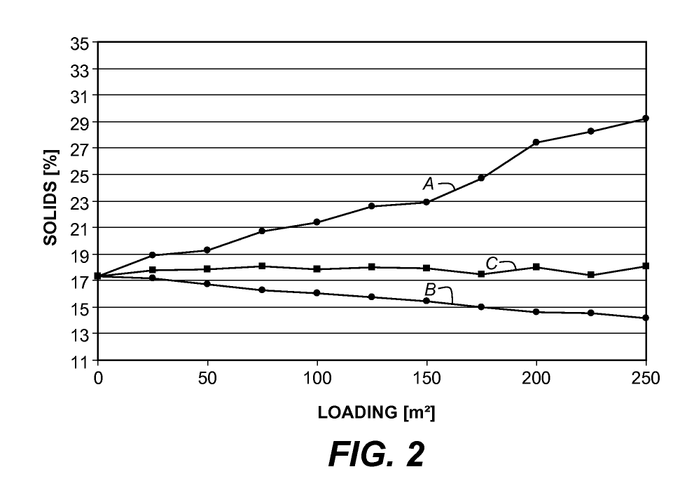

In this demonstration of the prior art (for example, the Agfa Azura process), samples of imaged lithographic printing plate precursors were processed with no replenishment of any type. The concentration (% solids) of the developer increased up to two times after a processing cycle (250 m² surface area processed using a 20 liter developer canister). The increase in % solids is shown as curve A in FIG. 2. After 150 m² of processed surface area, we observed dried developer residue that had been deposited onto the processed lithographic printing plates and processing rollers.

### Comparative Example 2

Samples of the same imaged lithographic printing plate precursors were processed in a processing cycle using water replenishment to keep a constant developer volume, similar to known prior art processes described for example in EP Publication 2,045,662 (noted above). The concentration (% solids) of the developer decreased during the processing cycle (250 m² surface area using a 20 liter developer canister) because of the steady addition of water to maintain developer volume. The decrease in % solids is shown as curve B in FIG. 2. This “dilution” over the processing cycle time lowered the developer activity and as a consequence, at the end of the processing cycle, some processed lithographic printing plates exhibited retained coating residue in fine screens.

### Invention Example 1

Other samples of imaged lithographic printing plate precursors were processed in a processing cycle according to the present invention. Water evaporated from the developer was replenished by setting replenishment to 17 ml/m². Thus, only part of the water removed from the developer was replaced and the developer volume was allowed to steadily decrease at a slow rate. The concentration (% solids) of the developer, shown as Curve C in FIG. 2, changed very little over the cycle and no coating residue was observed on the apparatus rollers or processed lithographic printing plates until the very end of the cycle (250 m² of surface are using a 20 liter developer canister). Thus, this process allowed a longer processing cycle with minimal deposit of coating residue.

### Invention Example 2

Other samples of imaged lithographic printing plate precursors were processed in a processing cycle according to the present invention. Water that evaporated from the developer was replenished by setting replenishment to 9 ml/m² during processing of imaged precursors and to 18 ml/hour during idle mode of the processor (for example, overnight). Thus, only part of the water removed from the developer was replaced and the developer volume was allowed to steadily decrease at a slow rate in processing mode, whereas in idle mode, the volume of the developing solution did not change. The concentration (% solids) of the developer changed very little over the processing cycle and no coating residue was observed on the apparatus rollers or processed lithographic printing plates until the very end of the processing cycle (250 m² of surface area processed using 20 liters of developer). This process allowed a longer processing cycle with minimal deposit of coating residue.

The invention has been described in detail with particular reference to certain embodiments thereof, but it will be understood that variations and modifications can be effected within the spirit and scope of the invention.

### PARTS LIST

8 Processing chamber
10 Arrow showing conveyance direction
12, 14, 16 Roller pairs
18 Developer
20 Spray devices
22, 24 Rotating brushes
26 Developer canister
28 Developer pump
30 Developer level sensor
40 Water
42 Water canister
44 Water pump
46 Computer
50 Conveyed precursor sensor
52 Drying chamber
54 Arrow to show used developer

1. A method for preparing a plurality of lithographic printing plates using a processing solution for development, comprising:
processing a plurality of imaged lithographic printing plate precursors in a processing apparatus having a container containing a developer having a pH greater than 7 by applying the developer to the imaged lithographic printing plate precursors to provide lithographic printing plates,
wherein water is added to the container containing the developer while allowing the total volume of the developer in the container to decrease as processing of the imaged lithographic printing plate precursors proceeds.

2. The method of claim 1 wherein the processing apparatus further comprises:
at least one spray device for applying the developer to the plurality of imaged lithographic printing plate precursors,
at least one pair of rollers for removing developer from the imaged lithographic printing plate precursors after the developer is sprayed thereon, and
a collection device for collecting developer that is not carried away by the plurality of lithographic printing plates.

3. The method of claim 1 wherein the processing apparatus further includes a container containing water that can be supplied to the container containing the developer.

4. The method of claim 1 wherein the water is added to the container containing the developer at a constant rate per unit area of imaged lithographic printing plate precursors being processed.

5. The method of claim 1 wherein the water is added to the container containing the developer at a constant rate per unit time that the developer is applied to the imaged lithographic printing plate precursors being processed.

6. The method of claim 1 wherein the developer is applied by a spray device and the water is added to a container containing the developer at a constant rate per unit time the spray device is activated to apply the developer to the imaged lithographic printing plate precursors.

7. The method of claim 1 wherein the non-volatile components in the developer is maintained in the container containing the developer within ±5% of the original non-volatile component concentration in fresh developer.

8. The method of claim 1 wherein the density of the developer is maintained in the container containing the developer within ±1% of the original density of fresh developer.

9. The method of claim 1 wherein the developer is designed to both develop the imaged lithographic printing plate precursor as well as provide a protective coating over the printing surface of the resulting lithographic printing plate.

10. The method of claim 1 wherein the developer has a pH of at least 8 and up to and including 11.

11. The method of claim 1 further comprising imaging the lithographic printing plate precursor to provide exposed and non-exposed regions prior to processing with the developer.

12. The method of claim 1 wherein the imaged lithographic printing plate precursor is processed by spraying the developer onto its imaged surface at a distance of at least 1 cm from the precursor surface.

13. The method of claim 1 for processing an imaged negative-working lithographic printing plate precursor comprising an imaged negative-working imagable layer to remove non-exposed regions in the imagable layer.
